(19) United States
(12) Patent Application Publication
(10) Pub. No.: US 2025/0361620 A1
(43) Pub. Date: Nov. 27, 2025

(54) SUBSTRATE PROCESSING METHOD AND SUBSTRATE PROCESSING SYSTEM

(71) Applicant: Tokyo Electron Limited, Tokyo (JP)

(72) Inventors: Junya SUZUKI, Nirasaki City (JP); Masahisa WATANABE, Nirasaki City (JP); Kouji SHIMOMURA, Nirasaki City (JP)

(21) Appl. No.: 19/294,359

(22) Filed: Aug. 8, 2025

Related U.S. Application Data
(63) Continuation of application No. PCT/JP2024/003954, filed on Feb. 6, 2024.

(30) Foreign Application Priority Data
Feb. 13, 2023 (JP) 2023-020295

(51) Int. Cl. C23C 16/56

(52) U.S. Cl. CPC C23C 16/56

(57) ABSTRACT

According to one embodiment of the present disclosure, there is provided a method of processing a substrate. The method includes preparing a substrate including a recess which has an overhang, forming a sacrificial layer on the substrate, forming a sealing layer on the sacrificial layer, the sealing layer including a higher etching resistance than the sacrificial layer; and plasma-etching the substrate on which the sacrificial layer and the sealing layer are formed to form a sealing portion that seals an upper portion of the recess, thereby forming an air gap structure.

### CROSS-REFERENCE TO RELATED APPLICATION

The application is a Bypass Continuation Application of PCT International Application No. PCT/JP2024/003954, filed on Feb. 6, 2024 and designating the United States, the international application being based upon and claiming the benefit of priority from Japanese Patent Application No. 2023-020295, filed on Feb. 13, 2023, the entire content of which is incorporated herein by reference.

### TECHNICAL FIELD

The present disclosure relates to a method of processing a substrate and a substrate processing system.

### BACKGROUND

Patent document 1 discloses a method of forming an air gap by gasifying an interlayer sacrificial film and removing the film through a groove and a gas-permeable film, and then forming a sealing layer that seals a vicinity of an opening of the groove after removing the interlayer sacrificial film.

### PRIOR ART DOCUMENT

### Patent Document

Patent Document 1: Japanese Patent Laid-open Publication No. 2010-062242

### SUMMARY

According to one embodiment of the present disclosure, there is provided a method of processing a substrate. The method includes preparing a substrate including a recess which has an overhang, forming a sacrificial layer on the substrate, forming a sealing layer on the sacrificial layer, the sealing layer including a higher etching resistance than the sacrificial layer; and plasma-etching the substrate on which the sacrificial layer and the sealing layer are formed to form a sealing portion that seals an upper portion of the recess, thereby forming an air gap structure.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a configuration of a substrate processing system.

FIG. 2 is a flowchart showing an example of a method of forming an air gap structure.

FIG. 3 is an example of a schematic cross-sectional view of a substrate W after being processed in step S203.

FIG. 4 is an example of a schematic cross-sectional view of a substrate W after being processed in step S204.

FIG. 5 is an example of a measurement result of a composition of a sealing portion.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of the present disclosure will be described with reference to the drawings. Throughout the drawings, same components are denoted by same reference numerals, and redundant explanations thereof may be omitted.

### [Substrate Processing System]

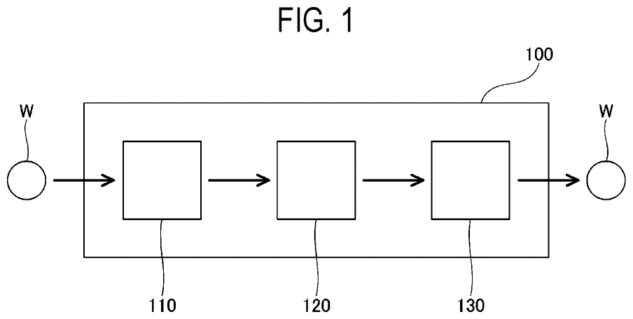

A substrate processing system 100 according to the present embodiment will be described with reference to FIG. 1. FIG. 1 is a diagram illustrating an example of a configuration of the substrate processing system 100.

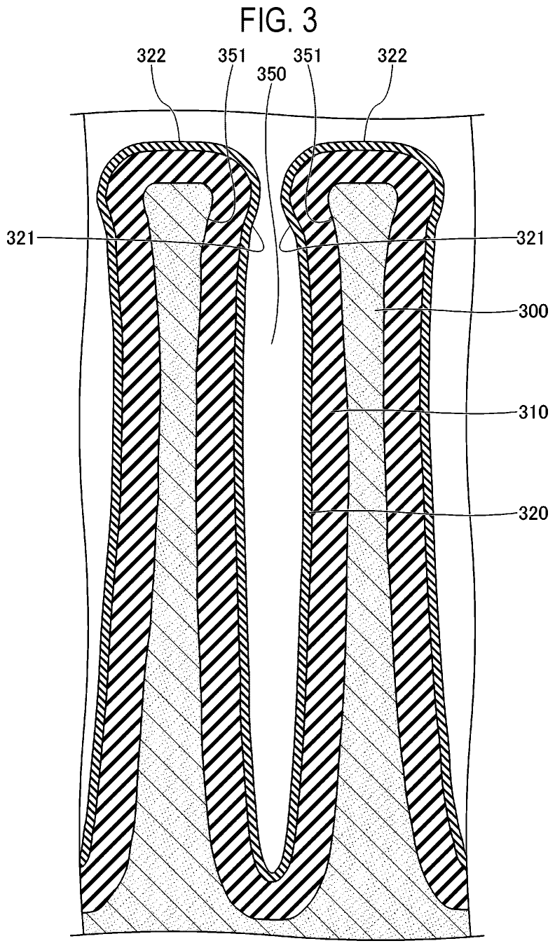

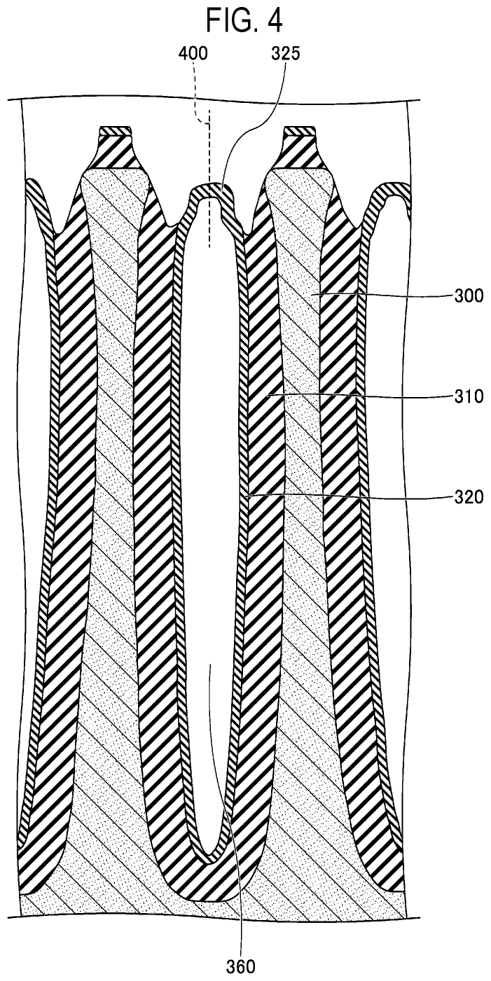

The substrate processing system 100 is a substrate processing system in which a substrate W including a trench-shaped recess 350 (see FIG. 3) or the like on a surface of the substrate is transferred, and an air gap structure 360 is formed in the substrate W by forming a sealing portion 325 (see FIG. 4) that seals an upper portion of the recess 350.

By forming the recess 350 into the air gap structure 360, the relative dielectric constant in the recess 350 can be lowered as compared to a case in which a dielectric (insulator) is filled in the recess 350.

In addition, a plurality of elements such as transistors is formed on the substrate W, and by forming the air gap structure 360 between one element and another adjacent element, occurrence of current leakage between the one element and the another element can be suppressed.

The substrate processing system 100 includes a first film forming apparatus 110, a second film forming apparatus 120, and an etching apparatus 130. The first film forming apparatus 110, the second film forming apparatus 120, and the etching apparatus 130 may be configured as separate apparatuses as shown in FIG. 1. Alternatively, the processing may be performed in the same apparatus. Further, the substrate W may be transferred between the first film forming apparatus 110, the second film forming apparatus 120, and the etching apparatus 130 in an air atmosphere or in a vacuum atmosphere.

The first film forming apparatus 110 is a film forming apparatus that forms a sacrificial layer 310 (see FIG. 3), which will be described later, on the substrate W. As the sacrificial layer 310, for example, a silicon oxide film or a film containing silicon oxide as a main component is formed. Specifically, SiO₂ or the like is formed as the sacrificial layer 310. The sacrificial layer 310 is not limited thereto, and may be, for example, SiOC, SiOCN, or the like which, since being formed without the use of plasma processing, has a low density. As the first film forming apparatus 110, a film forming apparatus such as an ALD (Atomic Layer Deposition) apparatus, a CVD (Chemical Vapor Deposition) apparatus, or the like can be used. In order to form the sacrificial layer 310 in the recess 350 with good coverage, it is preferable to use an ALD apparatus.

The second film forming apparatus 120 is a film forming apparatus that forms a sealing layer 320 (see FIG. 3), which will be described later, on the substrate W. As the sealing layer 320, for example, a film containing aluminum oxide, aluminum oxide hydroxide, or AlO doped with oxides such as Mg, Zn, and Mn, as a main component, is formed. Specifically, AlO, AlMgO, AlZnO, AlMnO, or the like is formed as the sealing layer 320. As the second film forming apparatus 120, a film forming apparatus such as an ALD apparatus, a CVD apparatus, or the like can be used. In order to form the sealing layer 320 in the recess 350 with good coverage, it is preferable to use an ALD apparatus.

The etching apparatus 130 is an apparatus that etches the sacrificial layer 310 and the sealing layer 320 (see FIG. 3) formed on the substrate W. The air gap structure 360 (see FIG. 4) is formed by etching the sacrificial layer 310 and the sealing layer 320. The etching apparatus 130 may be a parallel plate-type plasma etching apparatus. The parallel plate-type plasma etching apparatus generates a capacitively-coupled plasma (CCP). The plasma etching apparatus is a dry etching apparatus containing a CF-based gas (gas containing carbon (C) and fluorine (F)) as an etching gas, in which ions are collided in the vertical direction of the substrate W to perform etching in the vertical direction (anisotropic etching). The CF-based gas may be, for example, a C₄F₈ gas, a CF₄ gas, or the like. The etching gas may be added with an O₂ gas in addition to the CF-based gas. The etching gas may be added with an Ar gas or a N₂ gas.

The etching gas and etching conditions of the etching apparatus 130 may be the same as those for plasma-etching the sacrificial layer 310.

Here, in the plasma etching process of the etching apparatus 130, the sacrificial layer 310 and the sealing layer 320 have different etching resistances. Specifically, an etching rate of the sacrificial layer 310 is higher than an etching rate of the sealing layer 320. In other words, the sealing layer 320 has a higher etching resistance than the sacrificial layer 310. In other words, the sacrificial layer 310 is an easy-to-etch layer, and the sealing layer 320 is a hard-to-etch layer. For example, a dry etching rate of the sacrificial layer 310 made of SiO₂ is, for example, 50 nm/min, whereas a dry etching rate of the sealing layer 320 made of AlMgO is, for example, 2 nm/min.

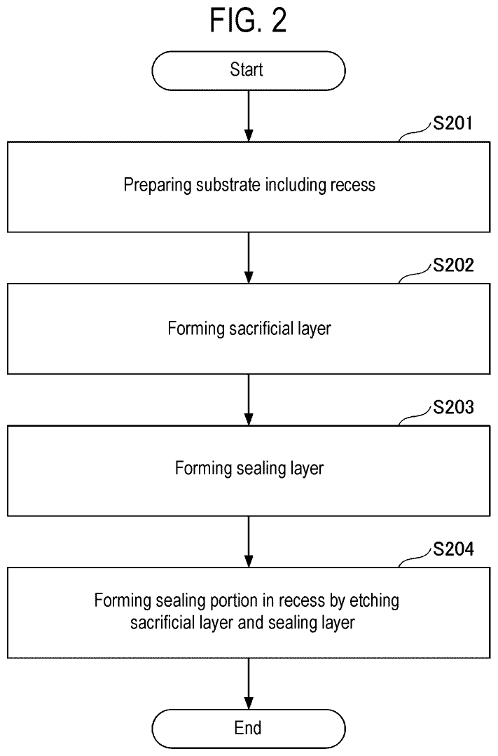

Next, a method of forming the air gap structure 360 (see FIG. 4) will be described with reference to FIGS. 2 to 4. FIG. 2 is a flowchart showing an example of the method of forming the air gap structure 360. FIG. 3 is an example of a schematic cross-sectional view of the substrate W after being processed in step S203. FIG. 4 is an example of a schematic cross-sectional view of the substrate W after being processed in step S204.

In step S201, a substrate W including a recess 350 is prepared. Here, the recess 350 having a trench shape or the like is formed on a surface of a layer 300 of the substrate W. The recess 350 has an overhang shape in which a width near an opening is narrower than a width at the center in the height direction. That is, an overhang portion 351, which is inclined beyond vertical toward the inside of the recess 350, is formed on a sidewall of the recess 350.

In step S202, a sacrificial layer 310 is formed on the substrate W. Here, the sacrificial layer 310 is formed on the substrate W by the first film forming apparatus 110. In the following description, it is assumed that SiO₂ is formed as the sacrificial layer 310.

In step S203, a sealing layer 320 is formed on the substrate W. Here, the sealing layer 320 is formed on the substrate W by the second film forming apparatus 120. In the following description, it is assumed that AlMgO is formed as the sealing layer 320.

As shown in FIG. 3, the substrate W has the sacrificial layer 310 formed on the sidewalls of the recess 350 and on the top of the recess 350 (upper surface of the layer 300). Here, the sacrificial layer 310 is formed on the sidewall of the recess 350 and on the top of the recess 350 with a substantially uniform thickness with good coverage. As a result, an overhang portion, which is inclined beyond vertical toward the inside of the recess 350, is formed on a sidewall of the sacrificial layer 310.

Further, in the substrate W, the sealing layer 320 is formed on the sacrificial layer 310. Here, the sealing layer 320 is formed along the sacrificial layer 310 with a substantially uniform thickness with good coverage. As a result, in the sealing layer 320 as well, an overhang portion 321, which is inclined beyond vertical toward the inside of the recess 350, is formed on the sidewall of the recess 350.

In step S204, the sacrificial layer 310 and the sealing layer 320 formed on the substrate W are etched to form a sealing portion 325 above the recess 350. Here, the sacrificial layer 310 and the sealing layer 320 formed on the substrate W are etched by the etching apparatus 130.

Here, the conditions for plasma-etching may be the same as those for etching the sacrificial layer 310 made of SiO₂. For example, a C₄F₈ gas added with an O₂ gas can be used as the etching gas.

Here, a change in shape during which the substrate W is plasma-etched will be described.

First, by colliding ions in the vertical direction of the substrate W by plasma-etching to etch in the vertical direction, a cleavage is formed between a top 322 and the overhang portion 321 of the sealing layer 320. For example, a cleavage is formed from a portion of a surface of the sealing layer 320 into which ions are incident by plasma-etching, where the curvature of the sealing layer 320 is small and a stress is applied.

Next, the sacrificial layer 310 is etched from the cleaved portion of the sealing layer 320 by continuing the plasma-etching. Here, the sacrificial layer 310 that is in contact with the overhang portion 321 of the sealing layer 320 formed on the upper portion of the sidewall of the recess 350 is etched.

As a result, the overhang portion 321 of the sealing layer 320 is in a cantilevered state in which an upper side is not supported by the sacrificial layer 310 and a lower side is supported by the sacrificial layer 310. Here, the overhang portion 321 of the cantilevered sealing layer 320 has one surface, which is a side surface of the recess 350, and the other surface on the opposite side (the surface that was in contact with the sacrificial layer 310 before etching). The other surface of the overhang portion 321 of the cantilevered sealing layer 320 faces the direction of incidence of ions incident by the plasma-etching.

Then, by continuing the plasma-etching further, ions are implanted into and/or collided with the other surface (the surface that was in contact with the sacrificial layer 310 before etching) of the overhang portion 321 of the cantilevered sealing layer 320 by the plasma-etching. As a result, the overhang portion 321 of the cantilevered sealing layer 320 is curved (deformed) toward the inside of the recess 350.

Then, upper ends of overhang portions 321 of the sealing layer 320 curved from both walls come into contact with each other at the upper portion (near the opening) of the recess 350. As a result, as shown in FIG. 4, the sealing portion 325 that seals the upper portion of the recess 350 is formed.

In addition, reaction by-products generated when the sacrificial layer 310 is etched are deposited on the curved overhang portion 321. The sealing portion 325 includes the deposited reaction by-products in addition to the overhang portions 321 of the sealing layer 320 curved from both walls.

As a result, the overhang portions 321 of the sealing layer 320 curved from both walls are bonded by the deposited reaction by-products.

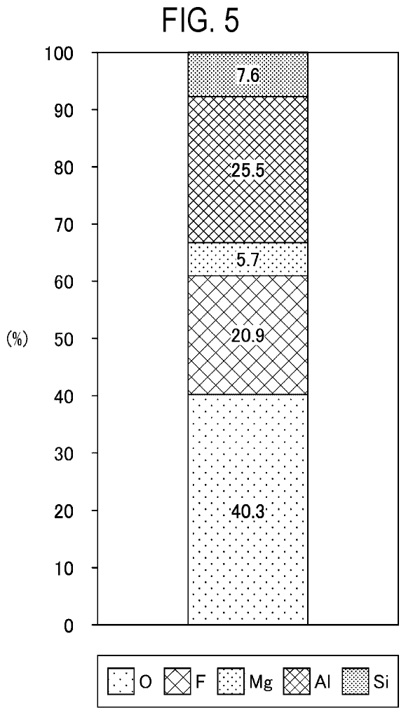

Here, an example of a composition of the sealing portion 325 will be described with reference to FIG. 5. FIG. 5 shows an example of a measurement result of the composition of the sealing portion 325 at a position indicated by a dashed line 400 in FIG. 4. Here, the composition of elements of the sealing portion 325 was measured by energy dispersive X-ray spectroscopy (EDX), and composition ratios of O, F, Mg, Al, and Si were detected from the measured composition.

The sealing portion 325 contains Al, Mg, and O derived from the sealing layer 320 (AlMgO).

The sealing portion 325 also contains Si, F, and O derived from reaction by-products generated when the sacrificial layer 310 (SiO₂) is plasma-etched using an etching gas (a C₄F₈ gas added with an O₂ gas).

Therefore, the sealing portion 325 is formed by the overhang portions 321 curved from both walls and the reaction by-products generated when the sacrificial layer 310 is etched.

As described above, as shown in FIG. 4, the sealing portion 325 is formed in the upper portion of the recess 350, and the opening of the recess 350 is closed by the sealing portion 325. In other words, the sealing portion 325 is formed as a lid that closes the opening of the recess 350. As a result, the air gap structure 360 is formed by the recess 350 and the sealing portion 325.

It is preferable for the etching rate of the sacrificial layer 310 to be 10 times or more higher than the etching rate of the sealing layer 320. This makes it possible to form the overhang portion 321 of the cantilevered sealing layer 320 while suppressing a loss of the sealing layer 320.

In addition, it is preferable for a film thickness of the sealing layer 320 to be within a range of 2 nm to 10 nm during film formation (at the end of S203). By setting the film thickness of the sealing layer 320 to 2 nm or more, the overhang portion 321 of the cantilevered sealing layer 320 can be stably formed. In addition, by setting the film thickness of the sealing layer 320 to 10 nm or less, a cleavage is formed in the sealing layer 320, and the sacrificial layer 310 can be etched from the cleavage. This makes it possible to stably form the cantilevered overhang portion 321 of the sealing layer 320. In addition, by setting the film thickness of the sealing layer 320 to 10 nm or less, the overhang portion 321 of the sealing layer 320 can be suitably curved (deformed) toward the inside of the recess 350, by ion implantation and/or collision.

In addition, it is preferable that the film thickness of the sealing layer 320 is thinner than the film thickness of the sacrificial layer 310. By setting the film thickness of the sacrificial layer 310 to be thicker, when the sacrificial layer 310 is etched from the cleavage of the sealing layer 320, the sacrificial layer 310 can be suitably etched.

In addition, the sealing layer 320 may be composed of two layers. One layer may be a layer formed of AlMgO, AlO, or the like, which is later curved to form the sealing portion 325, and on this layer, a passivation layer may be formed. By forming the passivation layer, the etching resistance of the sealing layer 320 can be improved.

In the above description, the upper ends of the overhang portions 321 curved from both walls are brought into contact with each other at the opening of the recess 350 to form the sealing portion 325. However, the present disclosure is not limited thereto.

The sealing portion 325 may have a structure in which the upper ends of the overhang portions 321 curved from both walls are not brought into contact with each other and a gap is formed between the upper ends of the overhang portions 321 curved from both walls. That is, the sealing portion 325 may have a gap. Even in a case in which the sealing portion 325 has such a gap, the opening of the recess 350 can be narrowed by forming the overhang portions 321 curved from both walls. In addition, after narrowing the opening of the recess 350 by plasma-etching, a film may be formed on the sealing portion 325 having the gap by a film forming method with low coverage, so as to close the gap of the sealing portion 325.

According to the present disclosure in some embodiments, it is possible to provide a method of processing a substrate and a substrate processing system for forming an air gap structure in a substrate.

The method of forming the air gap structure 360 according to one embodiment using the substrate processing system 100 has been described in the above, but the present disclosure is not limited to the above-described embodiment, and various modifications and improvements can be made within the scope of the gist of the present disclosure described in the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
preparing a substrate including a recess which includes an overhang;
forming a sacrificial layer on the substrate;
forming a sealing layer on the sacrificial layer, the sealing layer including a higher etching resistance than the sacrificial layer; and
plasma-etching the substrate on which the sacrificial layer and the sealing layer are formed to form a sealing portion that seals an upper portion of the recess, thereby forming an air gap structure.

2. The method of claim 1, wherein the plasma-etching the substrate includes:
forming a cleavage in the sealing layer;
etching the sacrificial layer from the cleavage of the sealing layer, thereby making the sealing layer formed on a sidewall of the recess in a cantilevered state; and
curving the cantilevered sealing layer toward the inside of the recess to form the sealing portion that seals the upper portion of the recess with the sealing layer, thereby forming the air gap structure.

3. The method of claim 2, wherein the cleavage is formed between a top of the sealing layer and an overhang portion of the sealing layer.

4. The method of claim 3, wherein the plasma-etching the substrate is dry etching using a CF-based gas as an etching gas.

5. The method of claim 4, wherein the plasma-etching the substrate further contains an O₂ gas as the etching gas.

6. The method of claim 1, wherein the plasma-etching the substrate is dry etching using a CF-based gas as an etching gas.

7. The method of claim 1, wherein the sacrificial layer is a silicon oxide film or a film containing silicon oxide as a main component.

8. The method of claim 1, wherein the sealing layer is a film containing any one selected from the group including aluminum oxide, aluminum oxide hydroxide, and AlO doped with oxides of Mg, Zn, and Mn, as a main component.

9. The method of claim 1, wherein, in the forming the sealing layer, a film thickness of the sealing layer is within a range of 2 nm to 10 nm during film formation.

10. The method of claim 1, wherein, in the plasma-etching the substrate, an etching rate of the sacrificial layer is 10 times or more higher than an etching rate of the sealing layer.

11. A substrate processing system that forms an air gap structure in a substrate including a recess which includes an overhang, comprising:
a first film forming apparatus that forms a sacrificial layer on the substrate;
a second film forming apparatus that forms a sealing layer on the sacrificial layer, wherein an etching resistance of the sealing layer higher than that of the sacrificial layer; and
an etching apparatus that plasma-etches the substrate on which the sacrificial layer and the sealing layer are formed to form a sealing portion that seals an upper portion of the recess, thereby forming the air gap structure.
